(19) United States
(12) Patent Application Publication
(10) Pub. No.: US 2017/0229300 A1
(43) Pub. Date: Aug. 10, 2017

(54) IMPRINT APPARATUS, IMPRINT METHOD, AND PATTERN FORMING METHOD

(71) Applicant: KABUSHIKI KAISHA TOSHIBA, Tokyo (JP)

(72) Inventors: Takumi OTA, Yokohama Kanagawa (JP); Kentaro KASA, Yokkaichi Mie (JP); Takayuki NAKAMURA, Machida Tokyo (JP)

(21) Appl. No.: 15/231,576

(22) Filed: Aug. 8, 2016

(30) Foreign Application Priority Data
Feb. 5, 2016 (JP) 2016-020901

(51) Int. Cl. H01L 21/027; B29C 59/02; B05C 5/02

(52) U.S. Cl. CPC H01L 21/0271; B05C 5/0291; B29C 59/022; B29K 2105/0058

(57) ABSTRACT

An imprint apparatus includes a template holder configured to hold a template that has a pattern formed thereon, the pattern to be transferred to a substrate by an imprinting process, a stage configured to hold the substrate, a liquid ejecting device configured to eject a resin precursor onto the substrate, an electric field plate configured to apply an electric field to the resin precursor on the substrate, and an electric field controller configured to apply a voltage to the electric field plate.

### CROSS-REFERENCE TO RELATED APPLICATIONS

This application is based upon and claims the benefit of priority from Japanese Patent Application No. 2016-020901, filed on Feb. 5, 2016, the entire contents of which are incorporated herein by reference.

### FIELD

An embodiment described herein relates generally to an imprint apparatus, an imprint method, and a pattern forming method.

### BACKGROUND

To manufacture semiconductor devices and electronic devices having a fine structure, an imprint method of transferring a pattern of a template (imprint mold) to a film to be processed is known.

### BRIEF DESCRIPTION OF THE DRAWINGS

FIG. 1 illustrates a configuration of an imprint apparatus according to an embodiment.

FIG. 2 is a plan view of a template stage of the imprint apparatus according to the embodiment.

FIG. 3 schematically illustrates an electric field generated by an electric field applying unit and a wafer stage of the imprint apparatus according to the embodiment.

FIG. 4 schematically illustrates bubbles attracted on surfaces of a resist through a bubble removing method according to the embodiment.

FIGS. 5A-5F illustrate an imprint method according to the embodiment.

FIGS. 6A-6C illustrate an imprint method according to the embodiment.

FIG. 7 schematically illustrates an imprint method according to a comparative example.

### DETAILED DESCRIPTION

In general, according to an embodiment, an imprint apparatus includes a template holder configured to hold a template that has a pattern formed thereon, the pattern to be transferred to a substrate by an imprinting process, a stage configured to hold the substrate, a liquid ejecting device configured to eject a resin precursor onto the substrate, an electric field plate configured to apply an electric field to the resin precursor on the substrate, and an electric field controller configured to apply a voltage to the electric field plate.

An example embodiment of an imprint apparatus and an imprint method will be explained below with reference to the accompanying drawings. The imprint apparatus and an imprint method disclosed herein are not limited to the example embodiment(s) described below.

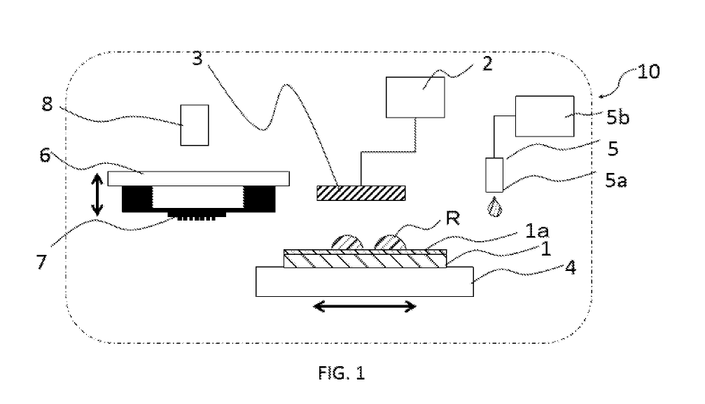

Hereinafter, an imprint apparatus and an imprint method according to an embodiment will be described with reference to FIGS. 1-5. In the following description of the drawings, elements which are the same as or similar to each other are represented using the same symbols.

FIG. 1 illustrates a configuration of an imprint apparatus according to an embodiment. An imprint apparatus 10 is configured to transfer a pattern in a template (original plate) to a resist material (resin) which formed on a film to be processed so for example, the pattern can be transferred to the film or to a substrate (processing target substrate) such as a wafer.

The imprint apparatus 10 according to the present embodiment includes an electric field controlling unit (controller) 2, an electric field applying unit 3, a wafer stage (moving stage) 4, a liquid dropping device (droplet ejecting device) 5, a template stage (template holder) 6, and a light irradiation device 8.

A wafer 1 is mounted on the wafer stage 4, and the wafer stage 4 can move in horizontal directions with the wafer 1 mounted thereon. A film 1a to be processed is placed on the wafer 1. The film 1a includes at least one of an oxide film, a carbon-containing film (e.g. organic film and pure carbon film), and a polysilicon film. Although the film 1a is depicted in FIG. 1 as is a single layer, the film 1a may be a multilayer film. When a resist R is applied as droplets on the wafer 1, the wafer stage 4 is moved below the liquid dropping device 5. Also, when the droplets of the resist R on the wafer 1 are imprinted by the template 7, the wafer stage 4 is moved below the template stage 6. These movements of the wafer stage 4 are performed by a conveying device (not shown), which is connected to the wafer stage 4.

A template having a light-transmitting property such as quartz template can be used as the template 7, but a material of the template 7 is not limited thereto.

The template stage 6 supports the template 7, and presses a patterned surface of the template 7 against the resist R droplets on the wafer 1. The template stage 6 presses the template 7 against the resist R droplets and releases the template 7 from the resist R by moving mainly in the vertical direction. The resist R used for the imprint process of the present embodiment is, for example, a photo-curable resin, but not limited thereto.

The template stage 6 also has a contact sensor (not shown). The contact sensor detects contact of the template 7 with the resist R, so that the template 7 does not contact the wafer 1 by moving down further.

The light irradiation device 8 is located above the template stage 6.

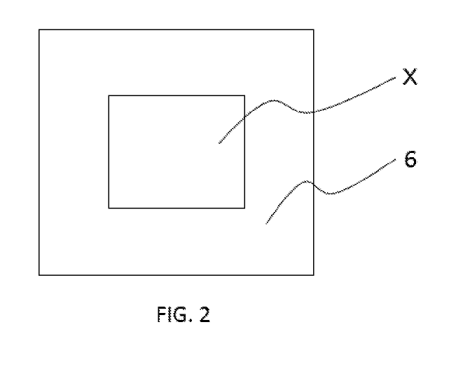

FIG. 2 is a plan view of the template stage 6 as viewed from above. As shown in FIG. 2, a central portion of the template stage 6 has a square-shaped cavity (opening) X. The template 7 is located directly below the cavity. The light irradiation device 8 which is located above the cavity emits light, which passes through the cavity, and then the template 7. The light is for example, UV light of 370 nm wavelength, but the light may not be UV light and may be selected according to composition of resist 7. The shape of the template stage 6 is not limited to the square as shown in FIG. 2.

The liquid dropping device 5 is configured to apply the resist R (or a precursor thereto) on the wafer 1 as droplets. The liquid dropping device 5 includes a liquid dropping unit 5a and a resist tank 5b. The liquid dropping unit 5a is, for example, an ink jet nozzle. In that case, the resist R is formed on the wafer 1 by an inkjet coating method. However, the coating method of the resist R is not limited thereto.

The electric field applying unit 3 (see FIG. 1) is for example, a square-shaped metal plate, which has a width of 30-50 mm in the horizontal direction. A thickness of the metal plate with respect to the vertical direction is, for example, about 1-10 mm. Any kind of metal can be used for the metal plate. Also, not only metal but also any kind of materials that is capable of generating or applying an electric field, except insulating materials, can be used for the electric field applying unit 3. The upper surface of the electric field applying unit 3 has a connector for connection to the electric field controlling unit 2. In the present embodiment, it is possible to remove bubbles in the resist R by generating an electric field from the electric field applying unit 3. This removal of bubbles helps prevent an incomplete pattern (pattern voids) from being formed when the resist R droplets containing bubbles are imprinted.

The electric field controlling unit 2 controls voltage applied to the electric field applying unit 3 for controlling intensity of the electric field generated from the electric field applying unit 3. The electric field controlling unit 2 applies a voltage, for example 100-200V, to the electric field applying unit 3. The voltage may be a direct current (DC) voltage or an alternating current (AC) voltage.

Next, the electric field generated from the electric field applying unit 3 when voltage is applied to the electric field applying unit 3 will be described.

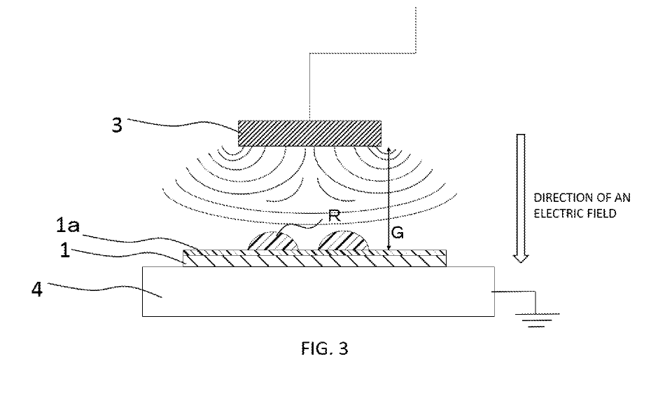

FIG. 3 is an enlarged cross-sectional view of the wafer 1, the wafer stage 4, and the electric field applying unit 3 shown in FIG. 1. The voltage is applied to the electric field applying unit 3 by the electric field controlling unit 2. The wafer stage is set to a ground potential (0V). As shown in FIG. 3, an electric field, equipotential lines of which are concentric circles, is generated from both ends of the electric field applying unit 3 towards the wafer stage 4. FIG. 3 shows a direction of the electric field by an arrow. In FIG. 3, the electric field applying unit 3 serves as a cathode, and the wafer stage 4 serves as an anode.

The electric field controlling unit 2 controls intensity of voltage applied to the electric field applying unit 3 in order to control intensity of the electric field to a value that is desirable to expose the droplets of the resist R formed on the wafer 1 to an electric field of uniform intensity. The intensity of the electric field and its uniformity change depending on voltage applied to the electric field applying unit 3 and a distance G between the wafer 1 and the electric field applying unit 3. As shown in FIG. 3, as the wafer stage 4 becomes closer to the electric field applying unit 3, difference of the intensity of the electric field between end portions of the electric field applying unit 3 and a central portion thereof increases. To the contrary, as the wafer stage 4 becomes farther from the electric field applying unit 3, the intensity of the electric field becomes more equal. The intensity of the electric field will become equal (within a desirable difference), when the distance G is, for example, 5 mm, and 100-200V is applied to the electric field applying unit 3.

Next, a method of removing bubbles in the droplets of the resist by using the electric field will be described.

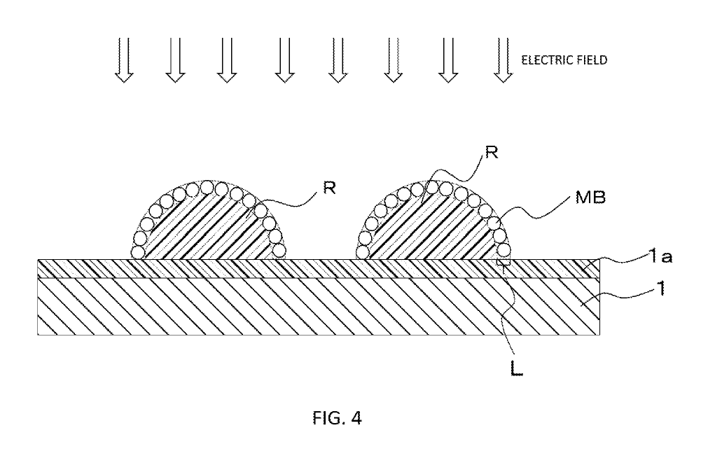

FIG. 4 is an enlarged view of droplets of the resist R formed on the wafer 1. The droplets of the resist R have been dropped from the liquid dropping device 5.

The resist R in the liquid dripping devise 5 passes through a filter of 10 nm mesh when the resist R is conveyed from the resist tank 5b to the liquid dropping unit 5a. During this conveyance, some bubbles are removed from the resist R. However, the filter may not be able to remove the bubbles completely, and thus a few microscopic bubbles may remain or otherwise form in the droplets of resist R which have been applied to the wafer 1 from the liquid dropping unit 5a. These microscopic bubbles are referred to as microbubbles MB. These microbubbles MB have a diameter of about 0.1-30 μm. At least a portion of surfaces of the microbubbles MB is covered with negative ions, and the microbubbles MB are charged entirely to the negative (about −40 mV).

As shown in FIG. 4, when the electric field is generated above the droplets of the resist R, the negatively-charged microbubbles MB in the resist R are attracted to the electric field and move upward in the droplets of the resist R. As a result, the upper side of the droplets of the resist R becomes a bubble layer L. More specifically, a part of the microbubbles MB in the droplets of the resist R are attracted to the electric field and released from the droplets into the atmosphere, and remaining microbubbles MB form the bubble layer L. Here, “above the resist” means that outer peripheral portions of the droplets of the resist R.

The droplets of the resist R underneath the bubble layer L are detected by the contact sensor when the droplets of the resist R are touched by the template 7 at a following step and a lower end of the template 7 contacts a lower end of a bubble layer (i.e., an upper end of the resist R: dotted lines in FIG. 4).

Once the contact sensor detects that the template 7 is contacting the resist R, the template 7 stops pressing, and the resist R is allowed to fill in a recess pattern of the template 7 by a capillary phenomenon. At this time, the rest of microbubbles MB in the droplets of the resist R disappear because of the pressure that the resist is filled into the template 7.

Next, an imprint method using the imprint apparatus 10 according to the present embodiment will be described in more detail.

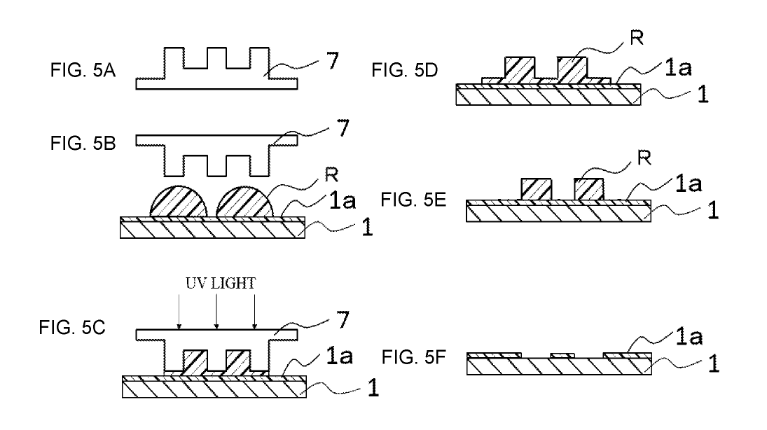

FIG. 5A-5F are cross-sectional views of the template 7, the wafer 1, and the resist R to describe an imprint method according to the present embodiment.

As shown in FIG. 5A, first, a template 7 on which a pattern is formed is provided. Then, the template 7 is set on a lower side of the template stage 6.

Also, the wafer 1 is loaded onto the wafer stage 4. The wafer stage 4 detects a position of the wafer 1 thereon, and moves the wafer 1 to a resist dropping position below the liquid dropping unit 5a. Then, droplets of the resist R are applied from the liquid dropping unit 5a to a targeting shot position of the film 1a on the wafer 1. When the application of the resist has completed, the wafer 1 is moved below the electric field applying unit 3.

The electric field applying unit 3 exposes the droplets of the resist R by the method described in FIG. 3, and causes a bubble layer to be formed on a surface of each of the droplets of the resist R.

Thereafter, as shown in FIG. 5B, the wafer 1 is moved below the template 7. Here, the droplets of the resist R are located below the template 7.

Then, imprint is performed on a predetermined shot position on the surface of the film 1a.

As shown in FIG. 5C, the template stage 6 lowers the template 7, so that the template 7 is pressed into the droplets of the resist R. When the contact sensor detects the contact of the template 7 with the upper end of the droplets of the resist R (i.e., the lower ends of the bubble layers), the template stage 6 stops lowering the template 7. At this moment, the microbubbles MB disappear because the resist R is filled into the recess pattern of the template 7 by the capillary phenomenon as described above.

The light irradiation device 8 emits light while the resist R remains in the recess of the template 7. The light passes through the template 7 that has optical transparency and reaches the resist R. As a result, the resist R is cured by light irradiation.

Next, as shown in FIG. 5D, by the template stage 6 moving upward, the resist R is released from the template 7.

The resist dropping process and the imprinting process described above are sequentially performed at all of shot positions of the film 1a.

When the imprinting process has been carried out for all shot positions of the film 1a, a residual film of the resist R formed at positions that do not correspond to the recess pattern of the template 7 is removed by etching as shown in FIG. 5E. In this way, the pattern of the template 7 is transferred to the resist R on the film 1a.

Next, as shown in FIG. 5F, the film 1a on the wafer 1 is etched using the resist R, in which the pattern of the template 7 has been transferred, as a mask. The resist R is removed after etching the film 1a. As a result, the pattern of the template 7 is transferred to the film 1a on the wafer 1.

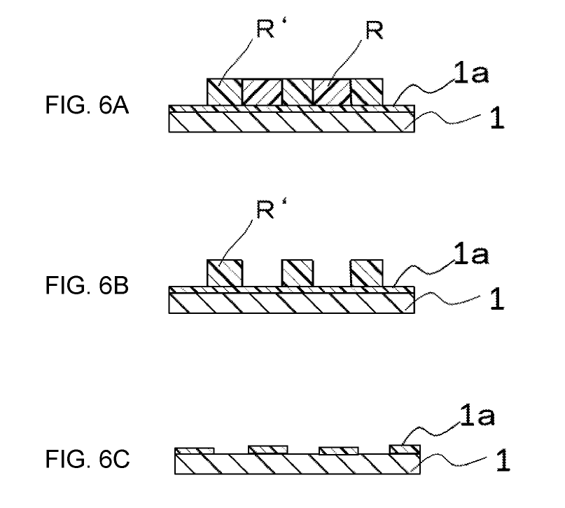

Further, it is also possible to form a reversed pattern on the film 1a by a method illustrated in FIGS. 6A-60. As shown in FIG. 6A, an oxide film R′ is formed on the resist R having the template pattern illustrated in FIG. 5E and planarized by polishing or the like. The oxide film R′ is an SOG (Spin On Glass) film which forms, for example, a SiO2 film.

Then, as shown in FIG. 6B, the resist R is removed by an aching process. Finally, the film 1a is etched using the oxide film R′ remaining on the film 1a as a mask (FIG. 6C). Through the process shown in FIG. 6A-6C, the pattern formed on the film 1a illustrated in FIGS. 5A-5F is turned in to the reversed pattern formed on the film 1a as illustrated in FIGS. 6A-6C. According to the present embodiment, it is possible to form a desired pattern by selecting an appropriate template pattern or an appropriate patterning method.

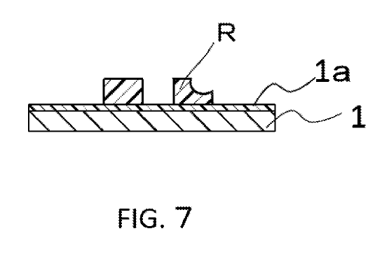

According to the imprint method using the imprint apparatus according to the present embodiment, it is possible to remove microbubbles from the applied, uncured resist by generating an electric field above the applied resist material before imprinting of the resist on the film 1a to be processed. This imprint method can suppress forming an incomplete pattern as shown in FIG. 7, which is formed by imprinting the resist in which a lot of microbubbles.

In the present embodiment, the resist R includes a photo-curable resin, and is cured by UV light, but curing of the resist R is not limited to this method. For example, the resist R may include a thermosetting resin and may be cured by heat. In this case, a heating device (heater) to heat the thermosetting resin can be set below (or within) the wafer stage 4 or above the template stage 6.

The imprint apparatus according to the present embodiment can also be applied to a nano-imprint process.

While certain embodiments have been described, these embodiments have been presented by way of example only, and are intended to limit the scope of the invention. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. An imprint apparatus, comprising:
a template holder configured to hold a template that has a pattern formed thereon, the pattern to be transferred to a substrate by an imprinting process;
a stage configured to hold the substrate;
a liquid ejecting device configured to eject a resin precursor onto the substrate;
an electric field plate configured to apply an electric field to the resin precursor on the substrate; and
an electric field controller configured to apply a voltage to the electric field plate.

2. The imprint apparatus according to claim 1, further comprising:
an irradiation device configured to irradiate the resin precursor on the substrate while the template is contacting the resin precursor.

3. The imprint apparatus according to claim 2, wherein the irradiation device is an ultraviolet light.

4. The imprint apparatus according to claim 2, wherein the irradiation device irradiates the resin precursor through the template.

5. The imprint apparatus according to claim 1, wherein the electric field plate is a metal plate.

6. The imprint apparatus according to claim 1, wherein the electric field plate serves as a cathode and the stage serves as an anode.

7. The imprint apparatus according to claim 1, wherein the liquid ejecting device includes an inkjet head.

8. The imprint apparatus according to claim 1, wherein
the liquid ejecting device is at a first horizontal position, the electric field plate is at second horizontal position, and the template holder is at a third horizontal position, and
the stage is moveable:
to the first horizontal position at which a droplet of the resin precursor is formed on the substrate by the liquid ejection device,
to the second horizontal position at which an electric field is applied to the droplet from the electric field plate, and
to the third horizontal position at which the droplet is contacted with the template in the template holder.

9. An imprint method, comprising:
forming droplets of a resin precursor on a substrate;
placing the droplets under an electric field;
after the droplets have been placed under the electric field, contacting the droplets with a template including a pattern formed thereon, such that the pattern is filled with the resin precursor; and
curing the resin precursor in the pattern of the template.

10. The imprint method according to claim 9, further comprising:
positioning the substrate having the droplets formed thereon in proximity with a plate to which a voltage is applied to generate the electric field.

11. The imprint method according to claim 10, wherein a distance between the substrate and the plate to be equal to or greater than 5 mm while the electric field is being generated.

12. The imprint method according to claim 10, wherein the voltage applied to the plate is equal to or greater than 100V and equal to and smaller than 200V.

13. The imprint method according to claim 10, wherein the voltage applied to the plate is greater than a potential of the film.

14. The imprint method according to claim 10, wherein the plate comprises a metal plate.

15. The imprint method according to claim 9, wherein the resin precursor is photocurable.

16. The imprint method according to claim 9, wherein the resin precursor is thermally curable.

17. A pattern forming method, comprising:
forming droplets of a resin precursor on a first film on a substrate;
placing the droplets on the first film under an electric field;
after the droplets have been placed under the electric field, contacting a pattern of a template and the droplets, such that the pattern is filled with the resin precursor;
curing the resin precursor in the pattern to form a cured resin pattern on the first film;
detaching the template from the cured resin pattern; and
patterning the first film using the cured resin pattern as a mask.

18. The pattern forming method according to claim 17, wherein the first film is one of an oxide film, a carbon-containing film, and a polysilicon film.

19. The pattern forming method of claim 17, wherein the resin precursor is photocurable.

20. The pattern forming method of claim 17, wherein the resin precursor is thermally curable.
